(19) United States
(12) Patent Application Publication
(10) Pub. No.: US 2026/0068096 A1
(43) Pub. Date: Mar. 5, 2026

(54) HEAT SINK LIFTING MECHANISM FOR PLUGGABLE OPTICAL MODULES

(71) Applicant: II-VI PHOTONICS, INC., Fuzhou (CN)

(72) Inventors: Jianfeng Ying, Fuzhou (CN); Jesse Zhu, Fuzhou (CN)

(21) Appl. No.: 19/196,234

(22) Filed: May 1, 2025

(30) Foreign Application Priority Data
Sep. 2, 2024 (CN) 202422144445.9

(51) Int. Cl. H05K 7/20; G02B 6/44; G06F 13/40

(52) U.S. Cl. CPC H05K 7/20418; G06F 13/409; G02B 6/4471; G06F 2213/40

(57) ABSTRACT

Systems and methods are provided for a heat sink lifting mechanism for pluggable optical modules. A movement mechanism may include a heat sink, a printed circuit board, and a cage. The cage may be affixed to the printed circuit board, and the heat sink may be located on top of the cage. A heat conductive material layer may be provided at the bottom of the heat sink. A compressed elastic member may be disposed between the heat sink and the cage. A lifting guide may be connected to a gap between the heat sink and the cage. The lifting guide may have a groove with a slope. A roller may be connected to the heat sink. The roller may be placed in the groove such that when the lifting guide is operated, the roller is driven to roll on the slope, thus causing the heat sink to be raised or lowered.

### CLAIM OF PRIORITY

This patent application claims priority to and claims benefit from Chinese (CN) Patent Application Serial No. 202422144445.9, filed on Sep. 2, 2024. The above identified application is hereby incorporated herein by reference in its entirety.

### TECHNICAL FIELD

Aspects of the present disclosure relate to fiber-optic communication related solutions. More specifically, certain implementations of the present disclosure relate to pluggable optical modules, and in particular to heat sink lifting mechanisms for use in pluggable optical modules.

### BACKGROUND

Limitations and disadvantages of conventional and traditional designs for managing heat in pluggable optical modules will become apparent to one of skill in the art, through comparison of such systems with some aspects of the present disclosure as set forth in the remainder of the present application with reference to the drawings.

### BRIEF SUMMARY

System and methods are provided for implementing and utilizing heat sink lifting mechanism for pluggable optical modules, substantially as shown in and/or described in connection with at least one of the figures, as set forth more completely in the claims.

These and other advantages, aspects and novel features of the present disclosure, as well as details of an illustrated embodiment thereof, will be more fully understood from the following description and drawings.

### BRIEF DESCRIPTION OF THE DRAWINGS

FIG. 1 illustrates an example pluggable optical module device incorporating a heat sink lifting mechanism in accordance with the present disclosure.

### DETAILED DESCRIPTION

The present disclosure is directed to fiber-optic communication related solutions. In particular, embodiments based on the present disclosure pertain to pluggable optical modules having improved performance, particularly by incorporating improved heat management features such as improved heat sink based components. In this regard, in the current trend of upgrading the power consumption of optical modules, the traditional heat sink used to dissipate heat from an optical module is in hard metal contact with the optical module, and as such the thermal resistance is very high. Increasing the thermal insulation material (TIM) between the heat sink and the optical module can effectively reduce the thermal resistance and improve the thermal efficiency. However, such an approach may have its own problems. For example, the TIM may be broken during the process of inserting and removing the optical module several times, and once the TIM is broken, the thermal resistance between the heat sink and the optical module may be greatly increased. Accordingly, solutions in accordance with the present disclosure may overcome the deficiencies of conventional designs, such as by providing a heat sink lifting mechanism for pluggable optical modules, so as to prevent or mitigate the risk of TIM breakage caused by plugging and unplugging of the optical module, and to effectively reduce the temperature of the optical module.

In various example implementations based on the present disclosure, such improvement may be achieved by use of a heat sink lifting mechanism, configured for use in a pluggable optical module, with the heat sink lifting mechanism comprising a heat sink (or radiator), a printed circuit board and a cage, with the cage being fixed to the printed circuit board, the heat sink being located on top of the cage, and the heat sink being provided with a layer of heat-conducting material at the bottom of the heat sink. An elastic member in a compressed state may be connected between the heat sink and cage, and a lifting guide rail may be slidingly connected to the gap between the heat sink and the cage. The lifting guide rail may be provided with a recess or a groove, with a slope, Further, a roller may be attached to the heat sink (or radiator), with the roller placed in the corresponding groove. The lifting guide rail may be driven to move, and the roller of the heat sink (or radiator) may be driven to roll on the slope, so as to drive the heat sink (or radiator) to be raised or lowered. Further, in some instances a handle may be fixed on the side of the lifting guide rail.

In an example operation of an implementation based on the present disclosure, during insertion of the pluggable optical module, the lifting mechanism is operated in a particular manner (e.g., pull or push, lift up or down, rotate, etc.). This may be done using the handle. This causes the riding heat sink to lift-up, and the TIM under the heat sink will be lifted up along with heat sink. In particular, TIM is lifted-up to a position where it will not be touched during the insertion of the pluggable optical module. The pluggable module is then inserted (e.g., into the cage). The lifting mechanism is then released (e.g., using the handle), such as by a reverse operation (e.g., push or pull; lift down or up, rotate in opposite direction, etc.). This causes the riding heat sink to move down, and thus the TIM will be pressed onto the surface of the pluggable optical module.

Removing the pluggable optical module may be done in a substantially similar manner. For example, before withdrawing the pluggable module, the lifting mechanism may be operated in the same manner as described above during the insertion process, thus lifting up the riding heat sink and moving the TIM away from the pluggable optical module. The pluggable optical module may then be withdrawn. Once the pluggable optical module is withdrawn (completely), the lifting mechanism is (optionally) released to move the riding heat sink down. Alternatively, the heat sink may be left in the open position—that is, lifted up—to allowing plugging of a different optical module.

In some instances, some of the elements described herein may be omitted. For example, in some implementations, the handle may be omitted, and the TIM itself may be used in operating the lift-up mechanism—e.g., a portion of the TIM may stick out to allow using it effectively as a “handle.”

As such, implementations in accordance with the present disclosure, adopting the various technical solutions described herein, may have the beneficial effects of incorporating a lifting mechanism that is installed in the gap between the heat sink (or radiator) and the cage of the pluggable optical module. Thus, when the optical module is to be inserted or pulled out, the lifting guide is only driven to move in order to drive the heat sink (or radiator) to be lifted up, and then the optical module is inserted or pulled out, which avoids frictional contact between the optical module and the heat-conducting material layer of the heat sink (or radiator) and thus avoids the risk of damage caused by the insertion or pulling out of the optical module, effectively reducing the temperature of the optical module. This can eliminate or at least reduce the friction contact between the optical module and the thermal conductive material layer of the heat sink, thus avoiding the risk of damage to the thermal conductive material layer that may be caused by the insertion and removal of the optical module, and effectively reducing the temperature of the optical module.

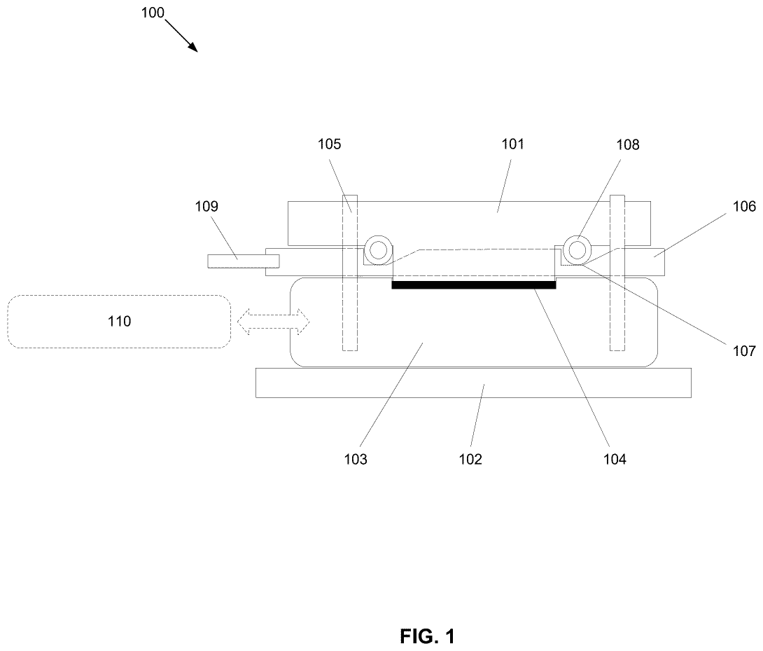

FIG. 1 illustrates an example pluggable optical module device incorporating a heat sink lifting mechanism in accordance with the present disclosure. Shown in FIG. 1 is a pluggable optical module device 100 incorporating a heat sink lifting mechanism. The pluggable optical module device 100 is configured to engage optical modules, with the engaging comprising plugging (inserting) and removing optical modules using the heat sink lifting mechanism.

As shown, the pluggable optical module device 100 comprises a heat sink (or radiator) 101, a printed circuit board 102, and a cage 103. In this regard, the cage 103 is crimped and fixed to the printed circuit board 102, and the heat sink 101 is located on the top of the cage 103. In particular, the heat sink 101 is attached to a layer of thermally conductive material (or heat conductive material layer) 104 at the bottom of the heat sink 101, and a compression elasticity member (or elastic member) 105 is attached to the heat sink 101 and the cage 103.

The gap between the heat sink (radiator) 101 and the cage 103 is slidingly connected with a lifting guide (or elevating guide rail) 106. The lifting guide 106 is provided with a groove (or recess) 107. The groove 107 has a slope, and the heat sink (radiator) 101 is connected with a roller 108, with the roller 108 placed in the corresponding groove 107. The lifting guide 106 is driven to move, and the roller 108 of the heat sink (radiator) 101 is driven to roll on the slope, so as to drive the heat sink (radiator) 101 to be raised or lowered. A handle 109 is fixed to the side of the lifting guide (elevating guide rail) 106. This allows for hand-held driving the lifting guide (elevating guide rail) 106 to move.

As shown in the example embodiment illustrated in FIG. 1, the high point of the slope of the recess 107 is on the right side, and pulling the lifting guide 106 to the left side raises the heat sink (radiator) 101, and pushing the lifting guide 106 on the right side lowers the heat sink (radiator) 101. However, the disclosure is not limited to such approach. For example, it is also possible to set the high point of the slope of the recess 107 on the left side, with the operation being just the opposite but substantially similar.

In an example operation of the embodiment illustrated in FIG. 1, before inserting an optical module 110, the handle 109 is first pulled to the left, making the lifting guide 106 move to the left, the roller 108 of the heat sink 101 is lifted up by rolling along the slope of the groove 107, and at this time, the heat conductive material layer 104 affixed on the bottom of the heat sink 101 is lifted up to a certain height at the same time. The optical module 110 is then inserted. In this regard, during the insertion of the optical module 110, the upper surface of the optical module 110 does not come into contact with the heat conductive material layer 104 at the bottom of the heat sink 101.

After the optical module 110 is inserted into place and locked by itself, the handle 109 is pushed to the right, so that the lifting guide 106 slides to the right, and at the same time drives the roller 108 to roll along the slope to the low position of the groove 107. Due to the elasticity of the elastic member 105, the heat sink 101 and the heat-conducting material layer 104 are pressed to the upper surface of the optical module 110.

Pulling out the optical module 110 is done in similar manner. The handle 109 is first pulled to the left, causing the heat sink 101 to raise, and as such the heat-conducting material layer 104 become out of contact with the upper surface of the optical module 110. The optical module 110 is then pulled out, and finally the handle 109 is pushed to the right so that the heat sink 101 is reset.

It should be understood by a person of ordinary skill in the art that FIG. 1 illustrates a non-limiting embodiment of the present disclosure, and as such a person of ordinary skill in the art may make a variety of changes or modifications to this embodiment without departing from the principle and substance of the disclosure, but these changes and modifications fall within the scope of the disclosure.

An example system, in accordance with the present disclosure, comprises a heat sink movement mechanism configured for handling pluggable optical modules, the heat sink movement mechanism comprising: a heat sink, a printed circuit board, a cage, and one or more handling components, wherein the cage is affixed to the printed circuit board, wherein the heat sink is located on top of the cage, wherein the cage is configured to receive a pluggable optical module, and wherein the one or more handling components are configured to enable movement of the heat sink relative to the cage during insertion and removing of the pluggable optical module.

In an example embodiment, the heat sink comprises a heat conductive material layer at a bottom of the heat sink.

In an example embodiment, the one or more handling components comprise a lifting guide.

In an example embodiment, the lifting guide comprises a groove, the groove having a slope.

In an example embodiment, the one or more handling components further comprise a roller, wherein the roller is connected to the heat sink, and wherein the roller is placed in or otherwise engages the groove.

In an example embodiment, the lifting guide is configured to, in response to being acted upon, drive the roller to roll on the slope, to cause the heat sink to raise or lower.

In an example embodiment, the heat sink movement mechanism further comprises an elastic member attached to the heat sink and the cage.

In an example embodiment, the one or more handling components comprise a handle configured for use in raising and lowering the heat sink.

In an example embodiment, the one or more handling components further comprise a lifting guide, and wherein the handle is affixed on a side of the lifting guide.

In an example embodiment, the movement of the heat sink comprises raising or lowering of the heat sink.

In an example embodiment, heat sink movement mechanism comprises a heat sink lifting mechanism.

As utilized herein, “and/or” means any one or more of the items in the list joined by “and/or”. As an example, “x and/or y” means any element of the three-element set {(x), (y), (x, y)}. In other words, “x and/or y” means “one or both of x and y.” As another example, “x, y, and/or z” means any element of the seven-element set {(x), (y), (z), (x, y), (x, z), (y, z), (x, y, z)}. In other words, “x, y and/or z” means “one or more of x, y, and z.” As utilized herein, the term “exemplary” means serving as a non-limiting example, instance, or illustration. As utilized herein, the terms “for example” and “e.g.” set off lists of one or more non-limiting examples, instances, or illustrations.

As utilized herein the terms “circuits” and “circuitry” refer to physical electronic components (e.g., hardware), and any software and/or firmware (“code”) that may configure the hardware, be executed by the hardware, and or otherwise be associated with the hardware. As used herein, for example, a particular processor and memory (e.g., a volatile or non-volatile memory device, a general computer-readable medium, etc.) may comprise a first “circuit” when executing a first one or more lines of code and may comprise a second “circuit” when executing a second one or more lines of code. Additionally, a circuit may comprise analog and/or digital circuitry. Such circuitry may, for example, operate on analog and/or digital signals. It should be understood that a circuit may be in a single device or chip, on a single motherboard, in a single chassis, in a plurality of enclosures at a single geographical location, in a plurality of enclosures distributed over a plurality of geographical locations, etc. Similarly, the term “module” may, for example, refer to a physical electronic component (e.g., hardware) and any software and/or firmware (“code”) that may configure the hardware, be executed by the hardware, and or otherwise be associated with the hardware.

As utilized herein, circuitry or module is “operable” to perform a function whenever the circuitry or module comprises the necessary hardware and code (if any is necessary) to perform the function, regardless of whether performance of the function is disabled or not enabled (e.g., by a user-configurable setting, factory trim, etc.).

Other embodiments of the invention may provide a non-transitory computer readable medium and/or storage medium, and/or a non-transitory machine readable medium and/or storage medium, having stored thereon, a machine code and/or a computer program having at least one code section executable by a machine and/or a computer, thereby causing the machine and/or computer to perform the processes as described herein.

Accordingly, various embodiments in accordance with the present invention may be realized in hardware, software, or a combination of hardware and software. The present invention may be realized in a centralized fashion in at least one computing system, or in a distributed fashion where different elements are spread across several interconnected computing systems. Any kind of computing system or other apparatus adapted for carrying out the methods described herein is suited. A typical implementation may comprise one or more application specific integrated circuit (ASIC), one or more field programmable gate array (FPGA), and/or one or more processor (e.g., x86, x64, ARM, PIC, and/or any other suitable processor architecture) and associated supporting circuitry (e.g., storage, DRAM, FLASH, bus interface circuits, etc.). Each discrete ASIC, FPGA, Processor, or other circuit may be referred to as “chip,” and multiple such circuits may be referred to as a “chipset.” Another implementation may comprise a non-transitory machine-readable (e.g., computer readable) medium (e.g., FLASH drive, optical disk, magnetic storage disk, or the like) having stored thereon one or more lines of code that, when executed by a machine, cause the machine to perform processes as described in this disclosure. Another implementation may comprise a non-transitory machine-readable (e.g., computer readable) medium (e.g., FLASH drive, optical disk, magnetic storage disk, or the like) having stored thereon one or more lines of code that, when executed by a machine, cause the machine to be configured (e.g., to load software and/or firmware into its circuits) to operate as a system described in this disclosure.

Various embodiments in accordance with the present invention may also be embedded in a computer program product, which comprises all the features enabling the implementation of the methods described herein, and which when loaded in a computer system is able to carry out these methods. Computer program in the present context means any expression, in any language, code or notation, of a set of instructions intended to cause a system having an information processing capability to perform a particular function either directly or after either or both of the following: a) conversion to another language, code or notation; b) reproduction in a different material form.

While the present method and/or system has been described with reference to certain implementations, it will be understood by those skilled in the art that various changes may be made and equivalents may be substituted without departing from the scope of the present method and/or system. In addition, many modifications may be made to adapt a particular situation or material to the teachings of the present disclosure without departing from its scope. Therefore, it is intended that the present method and/or system not be limited to the particular implementations disclosed, but that the present method and/or system will include all implementations falling within the scope of the appended claims.

What is claimed is:

1. A system, comprising:
a heat sink movement mechanism configured for handling pluggable optical modules, the heat sink movement mechanism comprising:
a heat sink;
a printed circuit board;
a cage; and
one or more handling components;
wherein the cage is affixed to the printed circuit board,
wherein the heat sink is located on top of the cage,
wherein the cage is configured to receive a pluggable optical module, and
wherein the one or more handling components are configured to enable movement of the heat sink relative to the cage during insertion and removing of the pluggable optical module.

2. The system of claim 1, wherein the heat sink comprises a heat conductive material layer at a bottom of the heat sink.

3. The system of claim 1, wherein the one or more handling components comprise a lifting guide.

4. The system of claim 3, wherein the lifting guide comprises a groove, the groove having a slope.

5. The system of claim 4, wherein the one or more handling components further comprise a roller, wherein the roller is connected to the heat sink, and wherein the roller is placed in or otherwise engages the groove.

6. The system of claim 5, wherein the lifting guide is configured to, in response to being acted upon, drive the roller to roll on the slope, to cause the heat sink to raise or lower.

7. The system of claim 1, wherein the heat sink movement mechanism further comprises an elastic member attached to the heat sink and the cage.

8. The system of claim 1, wherein the one or more handling components comprise a handle configured for use in raising and lowering the heat sink.

9. The system of claim 8, wherein the one or more handling components further comprise a lifting guide, and wherein the handle is affixed on a side of the lifting guide.

10. The system of claim 1, wherein the movement of the heat sink comprises raising or lowering of the heat sink.

11. The system of claim 1, wherein heat sink movement mechanism comprises a heat sink lifting mechanism.
